(19) United States
(12) Patent Application Publication
(10) Pub. No.: US 2024/0275281 A1
(43) Pub. Date: Aug. 15, 2024

(54) POWER SUPPLY CONTROLLER, SWITCHING POWER SUPPLY, ELECTRONIC APPARATUS, AND VEHICLE

(71) Applicant: ROHM CO., LTD., KYOTO (JP)

(72) Inventor: Hironori SUMITOMO, Kyoto (JP)

(21) Appl. No.: 18/441,403

(22) Filed: Feb. 14, 2024

(30) Foreign Application Priority Data
Feb. 15, 2023 (JP) 2023-021753

(51) Int. Cl. H02M 3/156; B60R 16/03; G11C 27/02

(52) U.S. Cl. CPC H02M 3/156; G11C 27/02; B60R 16/03

(57) ABSTRACT

A power supply controller which is configured to mainly control a switching power supply configured to generate an output voltage from an input voltage by driving an inductor current flowing through an inductor by switching a half-bridge output stage at a predetermined switching cycle, the power supply controller includes: a sample-and-hold circuit configured to generate a current feedback signal by sampling and holding the inductor current flowing through an upper switch element, which forms the half-bridge output stage, during an on period of the upper switch element; and a feedback control circuit configured to, based on the current feedback signal sampled and held in a certain switching cycle among switching cycles of the upper switch element that are repeated at the predetermined switching cycle, control a duty of the upper switch element in a subsequent switching cycle.

### CROSS-REFERENCE TO RELATED APPLICATION

This application is based upon and claims the benefit of priority from Japanese Patent Application No. 2023-021753, filed on Feb. 15, 2023, the entire contents of which are incorporated herein by reference.

### TECHNICAL FIELD

The present disclosure relates to a power supply controller, a switching power supply, an electronic apparatus, and a vehicle.

### BACKGROUND

In the related art, switching power supplies (so-called DC/DC converters) that generate a desired output voltage from an input voltage have been used as power supply means for various applications.

In the related art, as an example of the above-described technique, a current feedback system that detects a current flowing through a lower switch element of a half-bridge output stage by sampling and holding the current is disclosed.

### BRIEF DESCRIPTION OF DRAWINGS

The accompanying drawings, which are incorporated in and constitute a part of the specification, illustrate embodiments of the present disclosure.

FIG. 1 is a diagram showing a first embodiment (comparative example) of a switching power supply.

FIG. 2 is a diagram showing a second embodiment of a switching power supply.

FIG. 3 is a diagram showing an example of a sample-and-hold operation.

FIG. 4 is a diagram showing a configuration example of an upper sample-and-hold circuit.

FIG. 5 is a diagram showing a first example (comparative example) of current feedback control.

FIG. 6 is a diagram showing a second example of current feedback control.

FIG. 7 is a diagram showing a configuration example of an electronic apparatus.

FIG. 8 is a view showing an external appearance of a vehicle.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Switching Power Supply (First Embodiment)

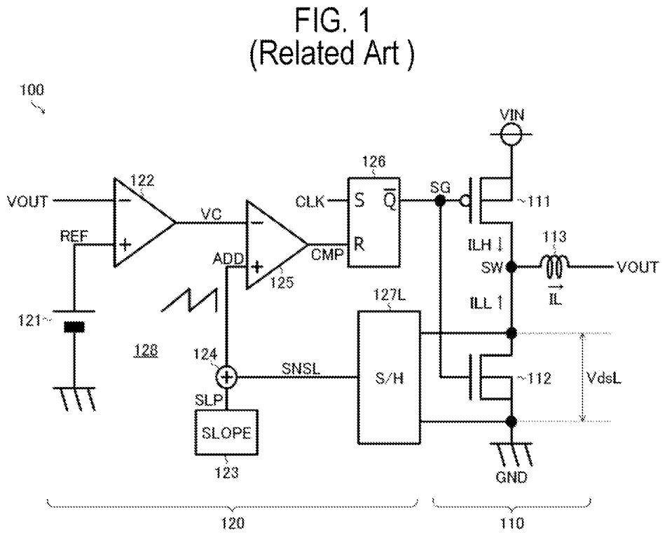

FIG. 1 is a diagram showing a first embodiment (corresponding to a comparative example compared to a second embodiment to be described later) of a switching power supply. A switching power supply 100 of the present embodiment is a step-down DC/DC converter configured to generate a desired output voltage VOUT from an input voltage VIN. Referring to the figure, the switching power supply 100 includes a switching output circuit 110 and a power supply controller 120.

The switching output circuit 110 includes an output transistor 111, a synchronous rectification transistor 112, and an inductor 113.

The output transistor 111 functions as an upper switch element forming a half-bridge output stage. The output transistor 111 may be, for example, a P-channel type metal oxide semiconductor field effect transistor (PMOSFET). A source of the output transistor 111 is connected to an application end of the input voltage VIN. A drain of the output transistor 111 is connected to an application end of a switch voltage SW. A gate of the output transistor 111 is connected to an application end of a gate drive signal SG. The output transistor 111 is turned off when the gate drive signal SG is at a high level, and turned on when the gate drive signal SG is at a low level.

The synchronous rectification transistor 112 functions as a lower switch element forming a half-bridge output stage. The synchronous rectification transistor 112 may be an NMOSFET (N-channel type MOSFET). A source of the synchronous rectification transistor 112 is connected to an application end (ground end) of a ground voltage GND. A drain of the synchronous rectification transistor 112 is connected to an application end of the switch voltage SW. A gate of the synchronous rectification transistor 112 is connected to an application end of the gate drive signal SG. The synchronous rectification transistor 112 is turned on when the gate drive signal SG is at a high level, and turned off when the gate drive signal SG is at a low level.

The output transistor 111 and the synchronous rectification transistor 112 are turned on/off in a complementary manner at a predetermined switching period Tsw in response to the gate drive signal SG. Due to this on/off operation, a rectangular waveform switch voltage SW pulse-driven between the input voltage VIN and the ground voltage GND is generated at a connection node (corresponding to the output end of the half-bridge output stage) between the output transistor 111 and the synchronous rectification transistor 112.

The word “complementary” mentioned above includes not only a case where the on/off states of the output transistor 111 and the synchronous rectification transistor 112 are completely reversed, but also a case where a simultaneous off period (dead time) of both transistors is provided.

A first end of the inductor 113 is connected to the application end of the switch voltage SW. The second end of the inductor 113 is connected to an application end of the output voltage VOUT. The inductor 113 connected in this way constitutes, together with a capacitor (not shown), an LC filter configured to rectify and smooth the switch voltage SW to generate the output voltage VOUT.

In this way, the switching power supply 100 drives an inductor current IL flowing through the inductor 113 to generate the output voltage VOUT from the input voltage VIN by switching the half-bridge output stage (that is, the output transistor 111 and the synchronous rectification transistor 112) in a complementary manner at the predetermined switching period Tsw.

The output transistor 111 may also be replaced with an NMOSFET. However, in that case, a bootstrap circuit or a charge pump circuit is required to raise a high level of the gate drive signal SG to a voltage value higher than the input voltage VIN.

Specifically, when a high voltage is applied to the switching output circuit 110, high-breakdown-voltage elements such as a power MOSFET, an insulated gate bipolar transistor (IGBT), and a SiC transistor may be used as the output transistor 111 and the synchronous rectification transistor 112, respectively. Further, GaN devices may be used as the output transistor 111 and the synchronous rectification transistor 112, respectively.

The power supply controller 120 is a semiconductor device (so-called power supply IC [Integrated Circuit]) configured to mainly control the switching power supply 100. Referring to the present figure, the power supply controller 120 includes a reference voltage generation circuit 121, an error amplifier 122, a slope signal generation circuit 123, an addition circuit 124, a comparator 125, an RS flip-flop 126, and a lower sample-and-hold circuit 127L.

The reference voltage generation circuit 121, the error amplifier 122, the slope signal generation circuit 123, the addition circuit 124, the comparator 125, and the RS flip-flop 126 may be understood as components of a feedback control circuit 128 configured to control the duty of the switching output circuit 110 such that the output voltage VOUT matches a target value.

The reference voltage generation circuit 121 generates a predetermined reference voltage REF (corresponding to a target set value of the output voltage VOUT). The reference voltage generation circuit 121 may be a DAC [Digital-to-Analog Converter] configured to convert a digital reference voltage set signal into an analog reference voltage REF. With such a configuration, it is possible to implement a soft start operation at startup or regulate the output voltage VOUT by using the above-described reference voltage set signal.

The error amplifier 122 generates an error signal VC according to a difference between the output voltage VOUT applied to an inverting input end (−) of the error amplifier 122 and the reference voltage REF applied to a non-inverting input end (+) thereof. The error signal VC increases when the output voltage VOUT is lower than the reference voltage REF, and decreases when the output voltage VOUT is higher than the reference voltage REF.

In a case where the output voltage VOUT does not fall within the input dynamic range of the error amplifier 122, a feedback voltage VFB according to the output voltage VOUT (for example, a divided voltage of the output voltage VOUT) may be input to the error amplifier 122.

The slope signal generation circuit 123 generates a slope signal SLP in the shape of a triangular wave, a sawtooth wave, or an n-th slope wave (for example, n=2) that rises during the on period Ton of the output transistor 111. For example, the slope signal SLP may start rising from a zero value at a turn-on timing of the output transistor 111, and may be reset to a zero value at a turn-off timing of the output transistor 111.

The addition circuit 124 adds the slope signal SLP and a lower current feedback signal SNSL to generate an addition signal ADD (=SLP+SNSL).

During the on period Ton of the output transistor 111, the comparator 125 compares the error signal VC input to the inverting input end (−) of the comparator 125 with the addition signal ADD input to the non-inverting input end (+) thereof to generate a comparison signal CMP. The comparison signal CMP is at a low level when the addition signal ADD is lower than the error signal VC, and is at a high level when the addition signal ADD is higher than the error signal VC. That is, the timing at which the comparison signal CMP rises from a low level to a high level becomes later as the error signal VC is higher, and becomes earlier as the error signal VC is lower.

The RS flip-flop 126 switches a logic level of the gate drive signal SG, which is output from an inverting output end (Q bar) of the RS flip-flop 126, in response to a clock signal CLK input to a set end (S) thereof and the comparison signal CMP input to a reset end (R) thereof. The clock signal CLK is a rectangular wave signal pulse-driven at a predetermined switching frequency fsw (=1/Tsw).

Specifically, when a pulse is generated in the clock signal CLK, the RS flip-flop 126 sets the gate drive signal SG to a low level (a logic level when the switch voltage SW is set to a high level). On the other hand, when a pulse is generated in the comparison signal CMP, the RS flip-flop 126 resets the gate drive signal SG to a high level (a logic level when the switch voltage SW is set to a low level).

In this way, the off timing of the output transistor 111 is determined according to the comparison signal CMP. Therefore, the on period Ton (high level period of the switch voltage SW) of the output transistor 111 becomes longer as a pulse generation timing of the comparison signal CMP is later, and conversely, becomes shorter as the pulse generation timing of the comparison signal CMP is earlier. That is, the on duty Don (Ton/Tsw) of the output transistor 111 becomes larger as the error signal VC is higher, and becomes smaller as the error signal VC is lower.

The lower sample-and-hold circuit 127L generates the lower current feedback signal SNSL by sampling and holding the inductor current IL (a lower inductor current ILL) flowing through the synchronous rectification transistor 112 during the on period of the synchronous rectification transistor 112 (the off period Toff of the output transistor 111).

The lower sample-and-hold circuit 127L may detect a voltage across the synchronous rectification transistor 112, that is, a drain-source voltage VdsL (=SW-GND), as a voltage signal corresponding to the lower inductor current ILL.

With the switching power supply 100 of the present embodiment, output feedback control using a current mode control method may be realized. Therefore, it is possible to improve the response characteristics of the output voltage VOUT as compared to output feedback control using a voltage mode control method.

In particular, in the switching power supply 100 of the present embodiment, a configuration is adopted in which the inductor current IL (lower inductor current ILL) flowing through the synchronous rectification transistor 112 is detected instead of the inductor current IL (upper inductor current ILH) flowing through the output transistor 111. According to this configuration, even in a case where the on period of the output transistor 111 becomes short (for example, during high voltage input or low voltage output), it is possible to perform the output feedback control using the current mode control method without a problem.

### <Considerations Regarding Current Feedback Control>

In recent years, as an advanced technology to improve power density of step-down DC/DC converters, the discloser of the present disclosure has proposed an ultra-high speed pulse control technology (Nano Pulse Control (registered trademark)) that may set an extremely low on duty Don. The above-mentioned on duty Don is defined as a ratio (Ton/Tsw) of the on period Ton of the output transistor 111 to the switching period Tsw.

Further, GaN devices are emerging as an approach to meet the high power requirements in the recent power supply IC market. For example, GaN devices are used as the aforementioned output transistor 111 and synchronous rectification transistor 112. A gate-source breakdown voltage of a GaN device is generally 10 V or less.

For example, when the drive of the output transistor 111 using a GaN device is controlled by the above-mentioned ultra-high speed pulse control technology, a minimum value of the period Ton of the output transistor 111 may be set to less than 20 ns (several ns to 20 ns).

In this way, in order to realize the switching power supply 100 with a large step-down ratio and a high oscillation frequency, it is necessary to set a very short on period Ton. Further, in order to perform current feedback control (so-called current mode control), it is also necessary to detect the inductor current IL.

Therefore, in the switching power supply 100 of the first embodiment, the inductor current IL (lower inductor current ILL) flowing through the synchronous rectification transistor 112 during the off period Toff (on period of the synchronous rectification transistor 112) which is longer than the on period Ton is sampled and held, and the held value is used to perform a current feedback control.

However, in the above-described current feedback control, the synchronous rectification transistor 112 is essential as a lower switch element forming the half-bridge output stage. Therefore, in the asynchronous rectification type switching power supply 100 that uses a diode as the lower switch element, it is difficult to perform current feedback control with low on-duty.

In view of the above considerations, a novel embodiment will be proposed below that can realize low on duty current feedback control even with an asynchronous rectification method.

### Switching Power Supply (Second Embodiment)

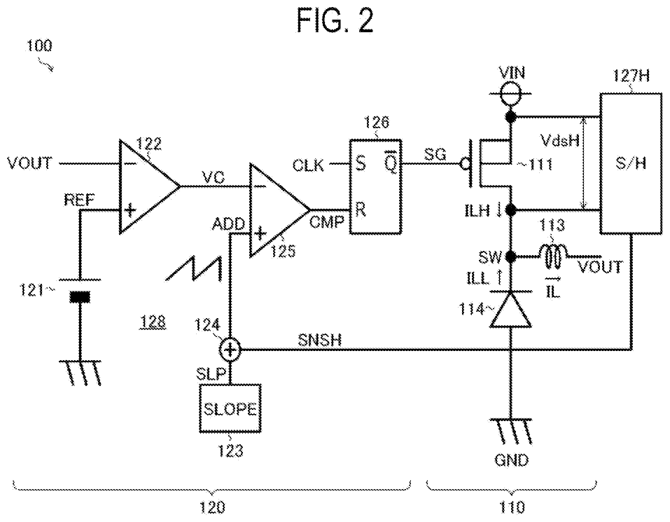

FIG. 2 is a diagram showing a second embodiment of the switching power supply. The switching power supply 100 of the present embodiment is based on the above-described first embodiment (FIG. 1) and includes an upper sample-and-hold circuit 127H in place of the lower sample-and-hold circuit 127L. Further, the switching power supply 100 of the present embodiment includes a diode 114 (for example, an external Schottky barrier diode) in place of the above-described synchronous rectification transistor 112.

Both the feedback control circuit 128 and the upper sample-and-hold circuit 127H may be integrated into a semiconductor device (the power supply controller 120).

In the following, the above-mentioned constituent elements are denoted by the same reference numerals as in FIG. 1, and therefore, the explanation thereof will not be repeated, and characteristics of the present embodiment will be mainly explained.

The upper sample-and-hold circuit 127H generates an upper current feedback signal SNSH by sampling and holding the inductor current IL (upper inductor current ILH) flowing through the output transistor 111 during the on period Ton of the output transistor 111.

For example, the upper sample-and-hold circuit 127H may sample and hold the upper inductor current ILH at a timing immediately before the output transistor 111 is turned off.

The upper sample-and-hold circuit 127H may detect a voltage across the output transistor 111, that is, a drain-source voltage VdsH (=VIN−SW), as a voltage signal corresponding to the upper inductor current ILH.

Further, the upper sample-and-hold circuit 127H may detect a voltage VsH (=Rs×ILH) across a sense resistor Rs (not shown) provided at a current path through which the upper inductor current ILH flows, as the voltage signal corresponding to the upper inductor current ILH.

The addition circuit 124 adds the slope signal SLP and the upper current feedback signal SNSH to generate an addition signal ADD (=SLP+SNSH).

That is, the feedback control circuit 128 realizes output feedback control using a current mode control method by receiving the input of the upper current feedback signal SNSH instead of the above-mentioned lower current feedback signal SNSL (FIG. 1).

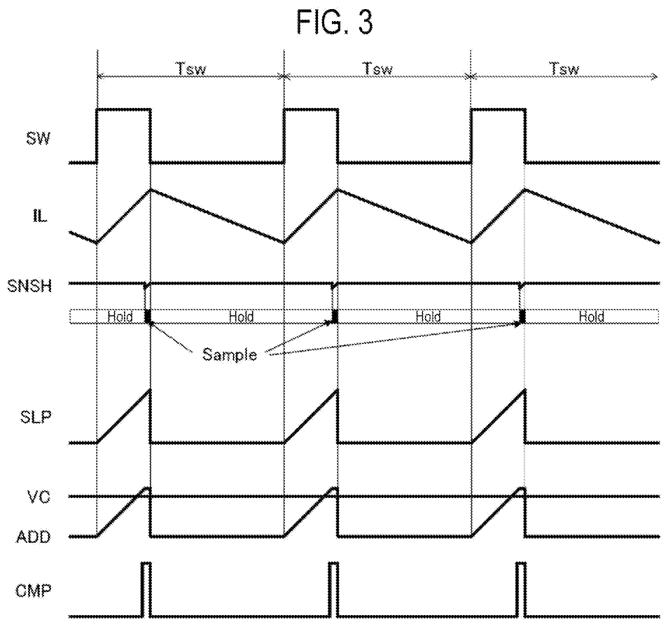

FIG. 3 is a diagram showing an example of a sample-and-hold operation. In this figure, the switch voltage SW, the inductor current IL, the upper current feedback signal SNSH, the slope signal SLP, the error signal VC, the addition signal ADD, and the comparison signal CMP are depicted sequentially from the top.

As shown in this figure, based on the upper current feedback signal SNSH sampled and held in a certain switching cycle among switching cycles of the output transistor 111 that are repeated at the switching period Tsw, the feedback control circuit 128 may control the duty of the output transistor 111 during a subsequent switching cycle.

According to this configuration, after sample-and-hold processing of the upper inductor current ILH is performed in a certain switching cycle, a process of comparison between the error signal VC and the addition signal ADD (=SLP+SNSH) may be performed before the start of the subsequent switching cycle. Therefore, an extremely narrow pulse (extremely short on period Ton) may be generated in the gate drive signal SG.

Further, the sample-and-hold processing of the upper inductor current ILH has to be completed within the above-mentioned on period Ton. However, in a case where a low on-resistance product is used as the output transistor 111, the drain-source voltage VdsH to be sampled becomes extremely low. Further, when a capacitor forming the upper sample-and-hold circuit 127H is integrated, the capacitor has an extremely small capacitance (several pF). Therefore, a time required to sample and hold the drain-source voltage VdsH is less than several ns, which is well within the on period Ton.

In this way, in the switching power supply 100 of the present embodiment, inductor current information is obtained from the upper switch element (output transistor 111) of the half-bridge output stage. Therefore, the lower switch element of the half-bridge output stage is not limited to the synchronous rectification transistor 112. For example, as shown in this figure, the diode 114 may be used as the lower switch element of the half-bridge output stage. That is, as a rectification method of the half-bridge output stage, not only the above-mentioned synchronous rectification method but also an asynchronous rectification method (diode rectification method) may be adopted.

As a result, low on duty current feedback control may be achieved not only with the synchronous rectification method but also with the asynchronous rectification method. In particular, the feedback control circuit 128 may be designed as a common core applicable to both the synchronous rectification method and the asynchronous rectification method. Therefore, a configuration of the power supply controller 120 may be flexibly changed by using one core.

Further, in the synchronous rectification method, the output transistor 111 and the synchronous rectification transistor 112 are generally built into the power supply controller 120 (semiconductor device). In this case, the power supply controller 120 receives not only the heat generated by the output transistor 111 but also the heat generated by the synchronous rectification transistor 112. Naturally, as the inductor current IL becomes larger, an amount of heat generated by the output transistor 111 and the synchronous rectification transistor 112 becomes larger. Therefore, the synchronous rectification method may be disadvantageous in handling a large current.

On the other hand, in the asynchronous rectification method, the diode 114 is generally attached externally to the power supply controller 120 (semiconductor device). Therefore, as compared to the above-mentioned synchronous rectification method, the number of heat sources in the power supply controller 120 is reduced. In view of this, it may be said that in order to handle a larger inductor current IL, it is more desirable to adopt the asynchronous rectification method than the synchronous rectification method.

In the related art, after the lower current feedback signal SNSN is sampled and held, a current proportional to the upper inductor current flows into a capacitor for hold. However, since such a signal processing is performed for slope generation, the upper inductor current is not sampled and held.

### <Upper Sample-and-Hold Circuit>

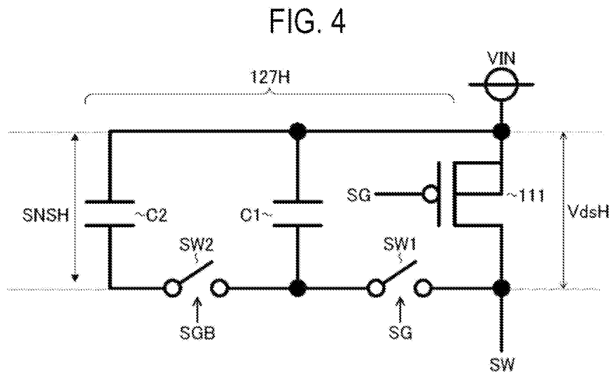

FIG. 4 is a diagram showing a configuration example of the upper sample-and-hold circuit 127H. The upper sample-and-hold circuit 127H in this configuration example includes capacitors C1 and C2 and switches SW1 and SW2.

A first end of the capacitor C1 is connected to the source of the output transistor 111. A second end of the capacitor C1 is connected to a first end of the switch SW1. A second end of the switch SW1 is connected to the drain of the output transistor 111.

A first end of the capacitor C2 is connected to the source of the output transistor 111. A second end of the capacitor C2 is connected to a first end of the switch SW2. A second end of the switch SW2 is connected to the second end of the capacitor C1 and the first end of the switch SW1.

The switch SW1 is turned on/off according to the gate drive signal SG. For example, the switch SW1 is turned on when the gate drive signal SG is at a low level. Further, the switch SW1 is turned off when the gate drive signal SG is at a high level.

The switch SW2 is turned on/off according to an inverted gate drive signal SGB (signal with an inverted logic level of the gate drive signal SG). For example, the switch SW2 is turned on when the inverted gate drive signal SGB is at a low level. Further, the switch SW2 is turned off when the inverted gate drive signal SGB is at a high level.

In this way, with the two-stage upper sample-and-hold circuit 127H, even in a case where the on-resistance of the output transistor 111 is high, it is possible to sample-and-hold the upper current feedback signal SNSH without a problem.

### <Current Feedback Control (Comparative Explanation)>

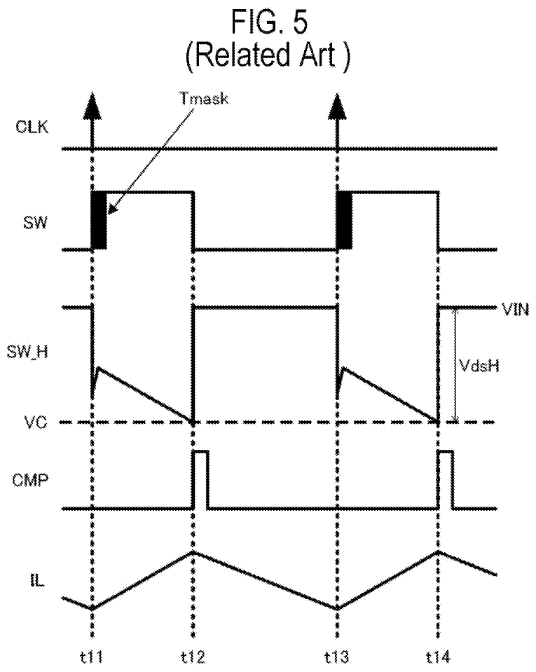

FIG. 5 is a diagram showing a first example of current feedback control (a general comparative example in which the sample-and-hold processing of the upper inductor current ILH is not performed). In this figure, the clock signal CLK, the switch voltage SW, a high-level extraction signal SW_H of the switch voltage SW, the error signal VC (indicated by a broken line), the comparison signal CMP, and the inductor current IL are depicted sequentially from the top.

The high-level extraction signal SW_H is a signal obtained by extracting only the high level (VIN-VdsH) of the switch voltage SW. The high-level extraction signal SW_H may be pulled up to the input voltage VIN during a low-level period (times t12 to t13 and times from time t14) of the switch voltage SW.

At time t11, when a pulse is generated in the clock signal CLK, the output transistor 111 is turned on, and the switch voltage SW rises to a high level. At this time, as the upper inductor current ILH increases, the high-level extraction signal SW_H decreases.

At time t12, when the high level-extraction signal SW_H falls below the error signal VC, the comparison signal CMP rises to a high level. As a result, the output transistor 111 is turned off, and the switch voltage SW falls to a low level. After time t12, basically the same signal processing as described above is repeated.

Immediately after the output transistor 111 is turned on, ringing may occur in the switch voltage SW. Therefore, a process of comparison between the high-level extraction signal SW_H and the error signal VC is deemed invalid until a predetermined mask period Tmask elapses after the switch voltage SW rises to the high level. Therefore, in the current feedback control shown in the figure, the high-level period of the switch voltage SW cannot be set to be shorter than the mask period Tmask.

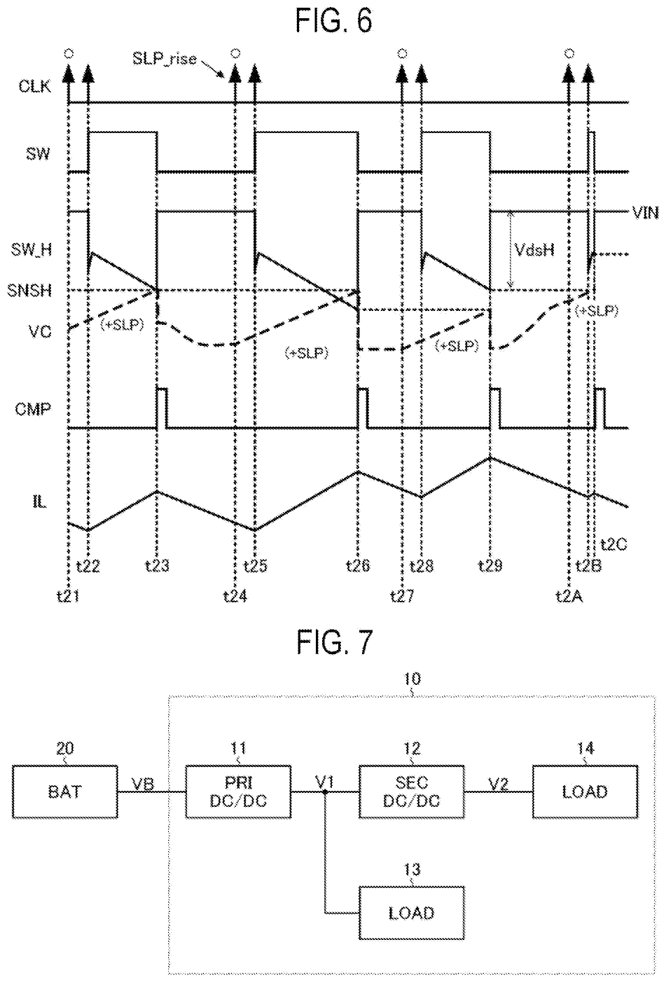

FIG. 6 is a diagram showing a second example of current feedback control (an example in which sample-and-hold processing of the upper inductor current ILH is performed). In this figure, the clock signal CLK, the switch voltage SW, the high-level extraction signal SW_H of the switch voltage SW, the upper current feedback signal SNSH (indicated by a small broken line), the error signal VC (indicated by a large broken line), the comparison signal CMP, and the inductor current IL are depicted sequentially from the top.

In the clock signal CLK, an arrow with a circle mark indicates a trigger for starting the rise of the slope signal SLP. Further, the error signal VC has sections (times t21 to t23, times t24 to t26, times t27 to t29, and times t2A to t2C) in which the slope signal SLP is added.

That is, in the current feedback control shown in this figure, unlike the above-described second embodiment (FIG. 2), the process of comparison between the error signal VC and the addition signal ADD (=SLP+SNSH) is not performed, but a process of comparison between the upper current feedback signal SNSH and an addition signal ADD′ (=VC+SLP) is performed. However, its technical significance remains unchanged.

At time t22, when a pulse is generated in the clock signal CLK, the output transistor 111 is turned on, and the switch voltage SW rises to a high level. At this time, as the upper inductor current ILH increases, the high-level extraction signal SW_H decreases.

At time t23, when the error signal VC (+SLP) exceeds the upper current feedback signal SNSH, the comparison signal CMP rises to a high level. As a result, the output transistor 111 is turned off, and the switch voltage SW falls to a low level. After time t23, basically the same signal processing as described above is repeated.

The upper current feedback signal SNSH may be held (updated), for example, at the pulse generation timing (timing immediately before the switch voltage SW falls to the low level) of the comparison signal CMP.

Further, in this figure, the slope start timing of the slope signal SLP is set to be earlier than the turn-on timing of the output transistor 111 (rising timing of the switch voltage SW). By performing such a signal processing, it is possible to set the high level period of the switch voltage SW (on period Ton of the output transistor 111) to be extremely short. However, the slope start timing of the slope signal SLP may coincide with the on timing of the output transistor 111.

### <Electronic Apparatus>

FIG. 7 is a diagram showing a configuration example of an electronic apparatus. The electronic apparatus 10 of this configuration example operates with a power supply voltage VB (for example, 12 to 48 V) supplied from a battery 20. Referring to the figure, the electronic apparatus 10 includes a primary power supply 11, a secondary power supply 12, and loads 13 and 14. The electronic apparatus 10 may be, for example, a vehicle-mounted apparatus.

The primary power supply 11 steps down the power supply voltage VB supplied from the battery 20 to generate a first output voltage V1 (for example, 5 V). The first output voltage V1 is output to, for example, the load 13 and the secondary power supply 12. In this way, the above-described switching power supply 100 (FIGS. 1 and 2) is suitable as the primary power supply 11 that has a high step-down ratio and requires high-frequency driving.

The secondary power supply 12 steps down or steps up the first output voltage V1 supplied from the primary power supply 11 to generate a second output voltage V2 (for example, 3.3 V). The second output voltage V2 is output to, for example, the load 14.

### <Application to Vehicle>

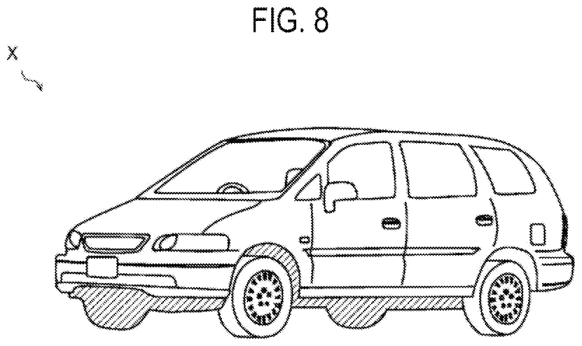

FIG. 8 is a view showing an external appearance of a vehicle. The vehicle X of this configuration example is equipped with various electronic apparatuses configured to operate with electrical power supplied from a battery.

The vehicle X includes not only engine vehicles, but also electric vehicles (xEVs such as BEV [Battery Electric Vehicle], HEV [Hybrid Electric Vehicle], PHEV/PHV [Plug-in Hybrid Electric Vehicle/Plug-in Hybrid Vehicle], or FCEV/FCV [Fuel Cell Electric Vehicle)/Fuel Cell Vehicle]).

The above-described switching power supply 100 may be incorporated into any of the electronic apparatuses mounted on the vehicle X.

### SUPPLEMENTARY NOTES

The above-described various embodiments will be comprehensively described below.

A power supply controller disclosed in the present disclosure is configured to mainly control a switching power supply configured to generate an output voltage from an input voltage by driving an inductor current flowing through an inductor by switching a half-bridge output stage at a predetermined switching cycle, and has a configuration that includes: a sample-and-hold circuit configured to generate a current feedback signal by sampling and holding the inductor current flowing through an upper switch element, which forms the half-bridge output stage, during an on period of the upper switch element; and a feedback control circuit configured to, based on the current feedback signal sampled and held in a certain switching cycle among switching cycles of the upper switch element that are repeated at the switching cycle, control a duty of the upper switch element in a subsequent switching cycle (first configuration).

The power supply controller of the first configuration may have a configuration that the sample-and-hold circuit samples and holds the inductor current at a timing immediately before the upper switch element is turned off (second configuration).

The power supply controller of the first or second configuration may have a configuration that the sample-and-hold circuit samples and holds a voltage across the upper switch element as a voltage signal according to the inductor current (third configuration).

The power supply controller of the first or second configuration may have a configuration that the sample-and-hold circuit samples and holds a voltage across a sense resistor provided at a current path through which the inductor current flows, as a voltage signal corresponding to the inductor current (fourth configuration).

The power supply controller of any one of the first to fourth configurations may have a configuration that the feedback control circuit includes: an error amplifier configured to generate an error signal according to a difference between the output voltage or a feedback voltage corresponding to the output voltage and a predetermined reference voltage; a slope signal generation circuit configured to generate a slope signal; an addition circuit configured to add the slope signal and the current feedback signal or the error signal to generate an addition signal; a comparator configured to compare the error signal or the current feedback signal and the addition signal to generate a comparison signal; and a flip-flop configured to generate a drive signal for the half-bridge output stage in response to the comparison signal (fifth configuration).

The power supply controller of the fifth configuration may have a configuration that a slope start timing of the slope signal is set to be earlier than an on timing of the upper switch element (sixth configuration).

The power supply controller of any one of the first to sixth configurations may have a configuration that a lower switch element forming the half-bridge output stage is a diode (seventh configuration).

The power supply controller of any one of the first to seventh configurations may have a configuration that the feedback control circuit and the sample-and-hold circuit are both integrated into a semiconductor device (eighth configuration).

Further, for example, a switching power supply disclosed in the present disclosure has a configuration that includes a power supply controller of any one of the first to eighth configurations (ninth configuration).

Further, for example, an electronic apparatus disclosed in the present disclosure has a configuration that includes: a primary power supply configured to generate a first output voltage from a power supply voltage; and a secondary power supply configured to generate a second output voltage from the first output voltage, wherein the primary power supply includes the switching power supply of the ninth configuration (tenth configuration).

Further, for example, a vehicle disclosed in the present disclosure has a configuration that includes the electronic apparatus of the tenth configuration (eleventh configuration).

### OTHERS

The various technical features disclosed in the present disclosure may be modified in various ways in addition to the above-described embodiments without departing from the gist of the technical creation. That is, the above-described embodiments should be considered to be illustrative in all respects and not restrictive. Further, the technical scope of the present disclosure is defined by the claims, and it should be understood that the technical scope of the present disclosure includes all changes that fall within the meaning and range equivalent to the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A power supply controller which is configured to mainly control a switching power supply configured to generate an output voltage from an input voltage by driving an inductor current flowing through an inductor by switching a half-bridge output stage at a predetermined switching cycle, the power supply controller comprising:
a sample-and-hold circuit configured to generate a current feedback signal by sampling and holding the inductor current flowing through an upper switch element, which forms the half-bridge output stage, during an on period of the upper switch element; and
a feedback control circuit configured to, based on the current feedback signal sampled and held in a certain switching cycle among switching cycles of the upper switch element that are repeated at the predetermined switching cycle, control a duty of the upper switch element in a subsequent switching cycle.

2. The power supply controller of claim 1, wherein the sample-and-hold circuit samples and holds the inductor current at a timing immediately before the upper switch element is turned off.

3. The power supply controller of claim 1, wherein the sample-and-hold circuit samples and holds a voltage across the upper switch element as a voltage signal according to the inductor current.

4. The power supply controller of claim 1, wherein the sample-and-hold circuit samples and holds a voltage across a sense resistor provided at a current path through which the inductor current flows, as a voltage signal corresponding to the inductor current.

5. The power supply controller of claim 1, wherein the feedback control circuit includes:
an error amplifier configured to generate an error signal according to a difference between the output voltage or a feedback voltage corresponding to the output voltage and a predetermined reference voltage;
a slope signal generation circuit configured to generate a slope signal;
an addition circuit configured to add the slope signal and the current feedback signal or the error signal to generate an addition signal;
a comparator configured to compare the error signal or the current feedback signal and the addition signal to generate a comparison signal; and
a flip-flop configured to generate a drive signal for the half-bridge output stage in response to the comparison signal.

6. The power supply controller of claim 5, wherein a slope start timing of the slope signal is set to be earlier than an on timing of the upper switch element.

7. The power supply controller of claim 1, wherein a lower switch element forming the half-bridge output stage is a diode.

8. The power supply controller of claim 1, wherein the feedback control circuit and the sample-and-hold circuit are both integrated into a semiconductor device.

9. A switching power supply comprising a power supply controller of claim 1.

10. An electronic apparatus comprising:
a primary power supply configured to generate a first output voltage from a power supply voltage; and
a secondary power supply configured to generate a second output voltage from the first output voltage,
wherein the primary power supply includes the switching power supply of claim 9.

11. A vehicle comprising the electronic apparatus of claim 10.
